(19) United States
(12) Patent Application Publication
(10) Pub. No.: US 2026/0253837 A1
(43) Pub. Date: Aug. 27, 2026

(54) Ion Milling Device and Processing Method Using Same

(71) Applicant: Hitachi High-Tech Corporation, Minato-ku, Tokyo (JP)

(72) Inventors: Shota AIDA, Tokyo (JP); Hisayuki TAKASU, Tokyo (JP)

(21) Appl. No.: 19/161,365

(22) PCT Filed: Mar. 20, 2023
(86) PCT No.: PCT/JP2023/011030

§ 371 Date: Sep. 2, 2025

(51) Int. Cl. H01J 37/305; H01J 37/08; H01J 37/20; H01J 37/24

(52) U.S. Cl. CPC H01J 37/3056; H01J 37/08; H01J 37/20; H01J 37/243

(57) ABSTRACT

A sample stage (104) is tiltable about a tilt axis (T) and rotates a sample (106) about a sample rotation axis (C) orthogonal to the tilt axis (T). A plurality of ion sources (101, 107, and 110) are adjusted by ion source movable mechanisms (102, 108, and 111) to which the ion sources (101, 107, and 110) are attached such that eccentricities, each of which is a distance between an ion beam center axis and the sample rotation axis (C) on a surface of the sample, are different from each other. A control unit (113) performs milling by irradiating the sample, which is rotated about the sample rotation axis (C) by the sample stage (104), with an unfocused ion beam from each of the plurality of ion sources (101, 107, and 110).

### TECHNICAL FIELD

The present invention relates to an ion milling device and a processing method using the ion milling device.

### BACKGROUND ART

An ion milling device irradiates a sample (for example, a metal, a semiconductor, glass, or ceramic) to be observed by an electron microscope with an unfocused ion beam. When atoms on a sample surface are ejected due to a sputtering phenomenon, the sample surface can be polished without stress or an internal structure of the sample can be exposed. The ion-milled sample surface or the exposed internal structure of the sample due to the irradiation with the ion beam serves as an observation surface of a scanning electron microscope or a transmission electron microscope.

PTL 1 discloses an invention related to an ion milling device that can achieve high processing accuracy, a wide processing area, and smoothness of a processing surface in processing with a plurality of ion beams.

### CITATION LIST

### Patent Literature

PTL 1: WO2021/152726A

### SUMMARY OF INVENTION

### Technical Problem

PTL 1 discloses a technique related to cross-sectional milling in which a mask for shielding an ion beam is disposed on a sample and a portion of the sample protruding from the mask is milled. In contrast, a method of processing a surface of a sample by irradiating the sample surface with an ion beam while rotating the sample is called planar milling. When planar milling is used, for example, to remove a polishing scratch from the sample surface, an ion beam center axis of the ion beam and a stage sample rotation axis are offset eccentrically, and the sample is irradiated with the ion beam while being rotated. A half-width of a profile of the emitted ion beam is typically about 0.5 mm to 1 mm. In this case, the vicinity of a center of the ion beam having a highest intensity is not continuously emitted to one location on the sample surface, and therefore, a smooth sample surface can be obtained in a wide range. Although an area thereof depends on an eccentricity, it is possible to smooth a range about twice a beam diameter at most.

There are a wide variety of applications of the planar milling, and the planar milling is used not only for removing a polishing scratch from a sample surface but also for delayering a semiconductor, particularly a three-dimensional device where memory cell arrays are stacked. However, in recent years, a larger three-dimensional device has been developed, and accordingly, there is an increasing demand for wider range processing than before.

### Solution to Problem

An ion milling device according to an embodiment of the invention includes: a sample chamber; a sample stage which is disposed in the sample chamber and on which a sample holder with a sample set thereon is mounted; a plurality of ion sources attached to the sample chamber via respective ion source movable mechanisms; and a control unit, in which the sample stage is tiltable about a tilt axis and rotates the sample about a sample rotation axis orthogonal to the tilt axis, the plurality of ion sources are adjusted by the respective ion source movable mechanisms to which the ion sources are attached such that eccentricities, each of which is a distance between an ion beam center axis and the sample rotation axis on a surface of the sample, are different from each other, and the control unit performs milling by irradiating the sample, which is rotated about the sample rotation axis by the sample stage, with an unfocused ion beam from each of the plurality of ion sources.

### Advantageous Effects of Invention

An object of the invention is to provide an ion milling device and a processing method that can perform planar milling in a wide range while reducing thermal damage to a sample. Other technical problems and novel features will become apparent from descriptions of the present description and the accompanying drawings.

### BRIEF DESCRIPTION OF DRAWINGS

FIG. 1A is a configuration example (top view) of an ion milling device according to a first embodiment.

FIG. 1B is a configuration example (side view) of the ion milling device according to the first embodiment.

FIG. 2A is a schematic diagram showing an ion source and a power supply circuit for applying a control voltage to the ion source.

FIG. 2B is a diagram showing a processed shape when a sample is processed by one ion source while changing an eccentricity.

FIG. 3 is a schematic diagram showing a state where the sample is irradiated with ion beams from a plurality of ion sources.

FIG. 4A is a schematic diagram three-dimensionally showing an arrangement of ion sources.

FIG. 4B is a diagram showing a method for setting an eccentricity for an i-th ion source.

FIG. 5 is a flowchart showing a series of operations from sample setting to an end of processing.

FIG. 6 is a configuration example (top view) of an ion milling device according to a second embodiment.

FIG. 7 is a diagram showing a method for adjusting an eccentricity for an ion source.

### DESCRIPTION OF EMBODIMENTS

Hereinafter, embodiments of the invention will be described with reference to the drawings.

### First Embodiment

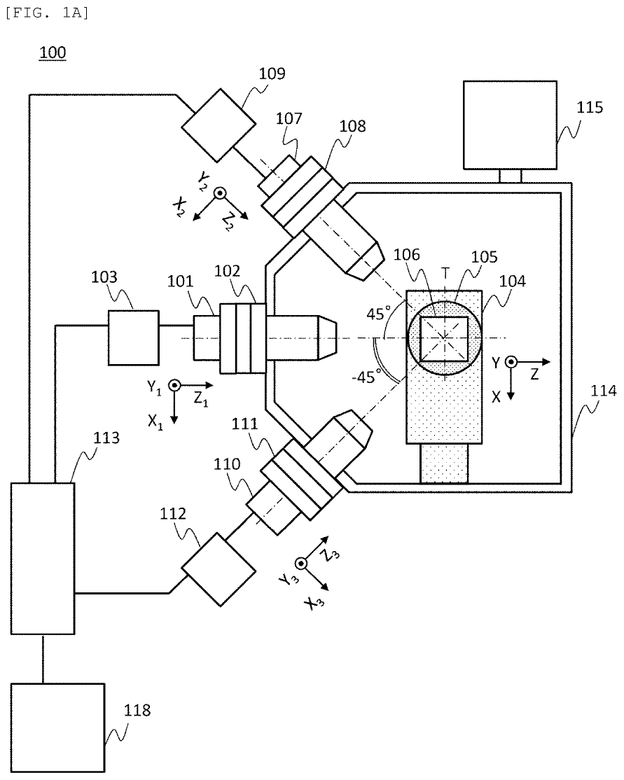

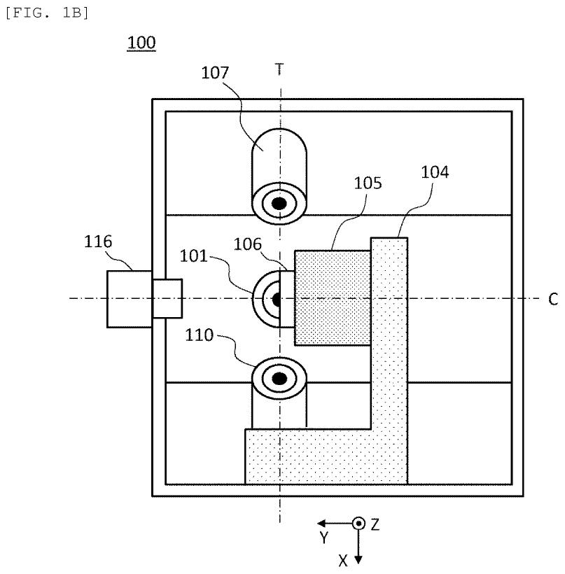

FIGS. 1A and 1B are schematic diagrams showing main parts of an ion milling device 100 in a first embodiment. FIG. 1A is a top view and FIG. 1B is a side view. The ion milling device 100 includes, as main components, a sample stage 104 for placing a sample 106 to be processed in a sample chamber 114, and a plurality of ion sources. Here, an example is shown in which three ion sources 101, 107, and 110 are provided. The sample stage 104 is tiltable about a tilt axis T and has a sample rotation axis C orthogonal to the tilt axis T. A sample holder 105 where the sample 106 is set is mounted on the sample stage 104. FIGS. 1A and 1B also show a coordinate system (X-axis, Y-axis, and Z-axis) of the sample stage. In this example, the tilt axis T extends in an X-axis direction, ion beam center axes of the plurality of ion sources are parallel to an XZ plane, and the sample rotation axis C extends in a Y-axis direction.

The three ion sources 101, 107, and 110 are attached to the sample chamber 114 via ion source movable mechanisms 102, 108, and 111, respectively. When an extending direction of an ion beam center axis of an i-th ion source (i=1 to 3) is defined as a Zᵢ-axis and an XᵢYᵢ plane perpendicular to the Zᵢ-axis is defined, an i-th ion source movable mechanism can move the i-th ion source in an Xᵢ-axis direction, a Yᵢ-axis direction, and a Zᵢ-axis direction. In this example, a coordinate system (X₁-axis, Y₁-axis, and Z₁-axis) of the first ion source movable mechanism 102 coincides with the coordinate system (X-axis, Y-axis, and Z-axis) of the sample stage.

Positions of the three ion sources 101, 107, and 110 can be adjusted such that ion beam center axes thereof, that is, Zᵢ-axes intersect at one point at an intersection of a surface of the sample 106 with the sample rotation axis C. At this time, the three ion sources are disposed such that an angle formed by the Z₁-axis and a Z₂-axis is 45° and an angle formed by the Z₁-axis and a Z₃-axis is −45°.

A first high-voltage power supply 103 that applies a control voltage for generating an ion beam is connected to the first ion source 101, a second high-voltage power supply 109 that applies a control voltage for generating an ion beam is connected to the second ion source 107, and a third high-voltage power supply 112 that applies a control voltage for generating an ion beam is connected to the third ion source 110. The high-voltage power supplies 103, 109, and 112 are controlled by a control unit 113. The control unit 113 is connected to a controller 118. The controller 118 is, for example, a personal computer (PC), and controls the entire device to execute milling by the device.

The sample chamber 114 is coupled to a vacuum pump 115 that can evacuate a pressure in the sample chamber 114 to a high vacuum (1.0×10⁻³ Pa or less). Further, as shown in FIG. 1B, an image sensor 116 for observing a processed shape of the sample 106 from above is provided. The image sensor 116 is desirably configured to capture an enlarged image of the processed shape of the sample 106 by an optical microscope or the like.

When the ion milling device is used as a pretreatment device for observing a sample surface or a sample cross-section with a scanning electron microscope or a transmission electron microscope, a Penning type effective for miniaturizing the device is often employed for the ion source. In the embodiment, the ion sources 101, 107, and 110 also employ the Penning type. As will be described in detail later, in the Penning type ion source, electrons are generated by causing Penning discharge by applying a high voltage (control voltage) from the high-voltage power supply to an internal electrode, and argon ions are generated by causing the generated electrons to collide with argon gas supplied from the outside. The ion source irradiates the sample 106 set at the sample holder 105 with the argon ions generated in this way as an unfocused ion beam.

Center axes of ion beams emitted from the first ion source 101, the second ion source 107, and the third ion source 110 intersect at one point on the sample rotation axis C of the sample stage 104. The one point is an intersection of the tilt axis T of the sample stage 104 with the sample rotation axis C, and is a eccentric position. Each ion source is movable in three directions, that is, the Xᵢ-axis direction, the Yᵢ-axis direction, and the Zᵢ-axis direction using the i-th ion source movable mechanism with reference to a position where the ion beam center axis Zᵢ passes through the eccentric position. The inside of the sample chamber 114 is maintained at the high vacuum by the vacuum pump 115, and a stable ion beam can be emitted to the sample without being affected by a gas in the sample chamber 114. At this time, the sample stage 104 rotates the sample 106 about the sample rotation axis C.

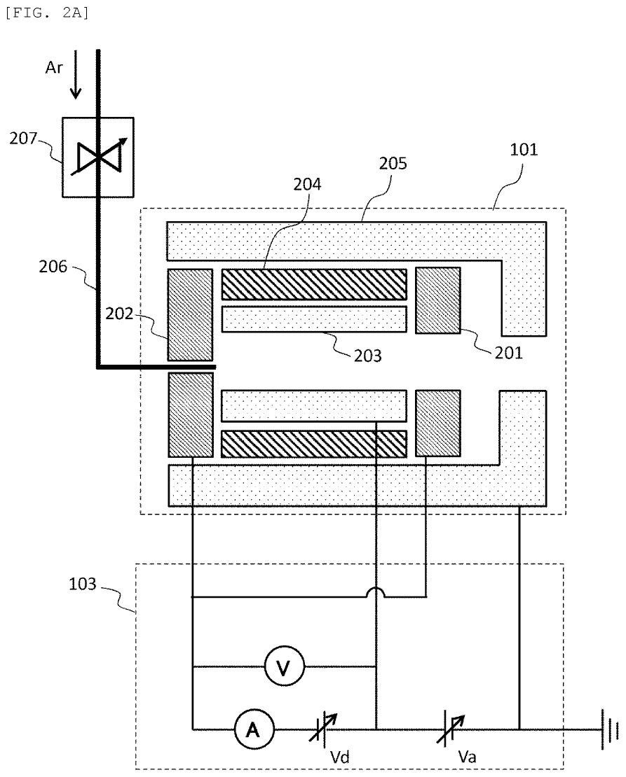

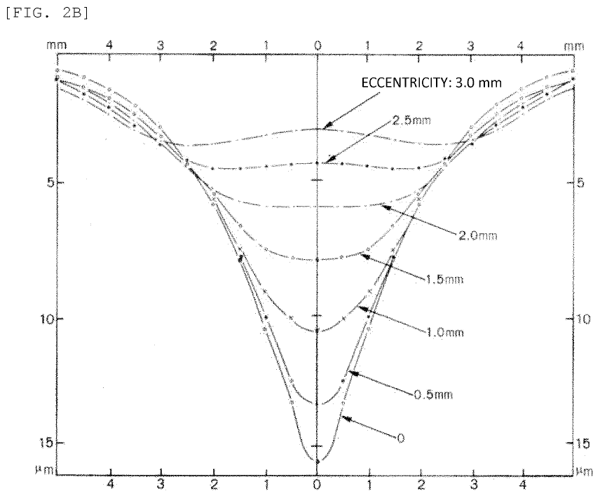

FIG. 2A is a schematic diagram showing the first ion source 101 and the first high-voltage power supply 103 employing the Penning type. In the figure, a power supply circuit that applies a control voltage to an electrode component of the first ion source 101 is extracted from the first high-voltage power supply 103 and shown. Since the second ion source 107 and the third ion source 110 have the same configuration as the first ion source 101, descriptions thereof will be omitted.

The ion source 101 includes, as main components, a first cathode 201, a second cathode 202, an anode 203, a permanent magnet 204, an acceleration electrode 205, a gas pipe 206, and a gas flow rate controller 207. In order to generate an ion beam, argon gas is injected into the ion source 101 through the gas pipe 206. In the ion source 101, the first cathode 201 and the second cathode 202 having the same potential face each other via the permanent magnet 204, and the anode 203 is disposed between the first cathode 201 and the second cathode 202. When a discharge voltage Vd from the high-voltage power supply 103 is applied between the cathodes 201, 202 and the anode 203, electrons are generated. Since a Lorentz force acts on the electrons generated by the permanent magnet 204 disposed in the ion source 101, the electrons perform a spiral motion. A flow rate is controlled by the gas flow rate controller 207, and the argon gas injected from the gas pipe 206 and the electrons collide with each other to form plasma, thereby generating argon ions. An acceleration voltage Va from the high-voltage power supply 103 is applied between the anode 203 and the acceleration electrode 205, and the generated argon ions are extracted by the acceleration electrode 205 and emitted as an ion beam.

FIG. 2B shows a processed shape when the sample is processed by one ion source while changing an eccentricity (a distance between the sample rotation axis C and the ion beam center axis Z on a sample surface). A horizontal axis represents a processing width [mm], and a vertical axis represents a processing depth [μm]. The sample rotation axis C is at a position of 0 on the horizontal axis. A profile of an ion beam from the ion source follows a Gaussian distribution in principle. Therefore, when the eccentricity is 0, that is, when the sample rotation axis C and the ion beam center axis Z coincide with each other, the processed shape becomes a shape according to the beam profile. On the other hand, by eccentrically offsetting the sample rotation axis C and the ion beam center axis Z, a planar milling range is expanded, and a processed shape having a flat surface is obtained. For example, when the eccentricity is 2.0 mm, it can be seen that a flat surface is formed around the position of the sample rotation axis C. However, when the eccentricity is further increased, the planar milling range is further expanded, while the flat surface is lost from the processed shape. For example, when the eccentricity is 3.0 mm, it can be seen that a convex surface is formed with the position of the sample rotation axis C serving as an apex.

FIG. 2B shows that a processed shape having a flat surface can be obtained by performing planar milling while eccentrically offsetting the sample rotation axis C and the ion beam center axis Z, and also shows that a depth and an area of the flat surface obtained by planar milling are limited since t eccentricity for obtaining the processed shape having the flat surface is limited. It is also possible to adjust the depth and the area of the flat surface by adjusting the ion beam profile, an irradiation angle (a tilt about the tilt axis T), and a processing time as parameters allowing the processed shape to be adjusted. However, for example, when the processing time, that is, a milling time is long, the sample may be damaged by heat generated at the sample due to the beam irradiation.

Therefore, in the embodiment, planar milling is performed using a plurality of ion sources having different eccentricities. With this configuration, it is possible to increase a degree of freedom in setting a condition for the ion milling device relative to a specification of the processed shape regarding the depth and the area of the flat surface. For example, one of the plurality of ion sources irradiates the sample with an ion beam by an eccentricity that forms a convex surface having the position of the sample rotation axis C as an apex, and another one irradiates the sample with an ion beam by an eccentricity that forms a concave surface having the position of the sample rotation axis C as a bottom, such that the processed shape can be flattened. Moreover, in this case, by processing using the plurality of ion sources, the milling time can be shortened, and thus thermal damage to the sample can be reduced.

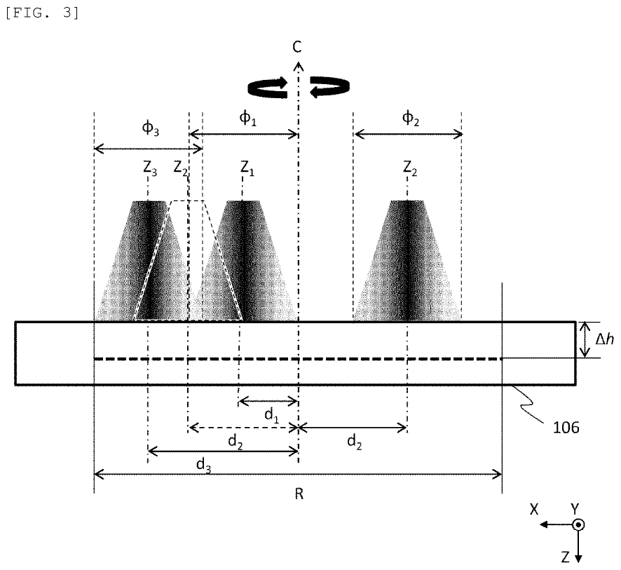

FIG. 3 is a schematic view showing a state where the sample 106 is irradiated with ion beams from three ion sources. Since the three ion sources are arranged at 45° intervals, the ion beam center axis Z₂ and the ion beam center axis Z₃ are tilted toward the ion beam center axis Z₁, but these ion beam center axes are shown in parallel for easy understanding. Although FIGS. 1A and 1B show a state where the ion beams emitted from the respective ion sources intersect at one point on the sample rotation axis C (initial state), an eccentricity d can be provided by moving the ion source movable mechanism to which each ion source is attached. Let d₁ be an eccentricity and φ₁ be an ion beam diameter on the surface of the sample 106 of the first ion source 101, d₂ be an eccentricity and φ₂ be an ion beam diameter on the surface of the sample 106 of the second ion source 107, d₃ be an eccentricity and φ₃ be an ion beam diameter on the surface of the sample 106 of the third ion source 110, and d₁<d₂<d₃. In order to facilitate understanding of a positional relationship of ion beams, in FIG. 3, an ion beam from the second ion source 107 is also shown at a symmetrical position relative to the sample rotation axis C.

In this case, the planar milling range diameter R is R=2d₃+φ₃, and at this time, it is recommended that all of the following inequalities (Equation 1) to (Equation 6) are satisfied.

$${d}_{1} < {φ}_{1} / 2 \qquad ( Equation 1 )$$

$${φ}_{1} / 2 < {d}_{2} - {d}_{1} \qquad ( Equation 2 )$$

$${φ}_{2} / 2 < {d}_{2} - {d}_{1} \qquad ( Equation 3 )$$

$${φ}_{2} / 2 < {d}_{3} - {d}_{2} \qquad ( Equation 4 )$$

$${φ}_{3} / 2 < {d}_{3} - {d}_{2} \qquad ( Equation 5 )$$

$${d}_{3} - {d}_{2} < {d}_{2} - {d}_{1} \qquad ( Equation 6 )$$

By satisfying (Equation 1) to (Equation 5), the ion beam is irradiated in the entire region of the planar milling range diameter R. In addition, as the eccentricity d increases, an angle of incidence of the ion beam relative to the sample surface increases, and thus an amount of ion beam irradiation per unit time decreases. Therefore, a variation in a processing depth Δh increases outside a planar milling range, in other words, flatness of the processed shape may be lost. Therefore, when planar milling is performed using three or more ion sources, it is desirable to set the eccentricity such that the amount of beam irradiation per unit time becomes as uniform as possible, and overlap with an ion beam from an ion source adjacent to an inner side is maximized as the eccentricity increases, that is, (Equation 6) is satisfied.

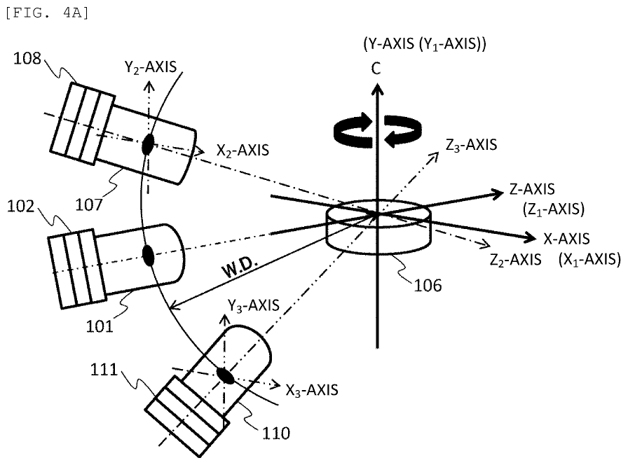

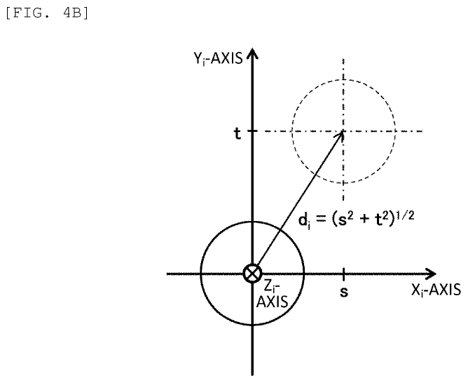

FIG. 4A is a schematic diagram three-dimensionally showing an arrangement of the i-th (i=1 to 3) ion source (101, 107, or 110) in FIGS. 1A and 1B. When the Xᵢ-axis, the Yᵢ-axis, and the Zᵢ-axis of the i-th ion source movable mechanism (102, 108, or 111) are at initial positions, the Zᵢ-axis (i=1 to 3) intersects the sample rotation axis C at one point (initial state). The three ion sources are on the same plane (XZ plane), and distances (working distance (W.D.)) of the ion sources from the intersection on the sample rotation axis C are all the same value. An eccentricity dᵢ from the sample rotation axis C can be set by moving the Xᵢ-axis of each ion source by s and the Yᵢ-axis by t. At this time, as shown in the schematic diagram of the i-th ion source when viewed from the Zᵢ-axis in FIG. 4B, the eccentricity dᵢ=(s²+t²)^{1/2}) is satisfied. Note that this calculation formula is a calculation formula in a state where the sample 106 is tilted about the tilt axis T such that the i-th ion source and the sample 106 face each other, and it is needless to say that even when a tilt of the tilt axis T and inclination of the Zᵢ-axis with respect to a normal direction of the sample surface are at any angles, magnitude of dᵢ can be geometrically calculated by including these angles.

The ion source movable mechanisms 102, 108, and 111 may manually move the attached ion sources, or may perform automatic control by incorporating a drive motor on each axis of each movable mechanism. In the case of automatic control, for example, each drive motor is connected to the control unit 113, and an amount of movement on each axis can be input from the controller 118 to the control unit 113.

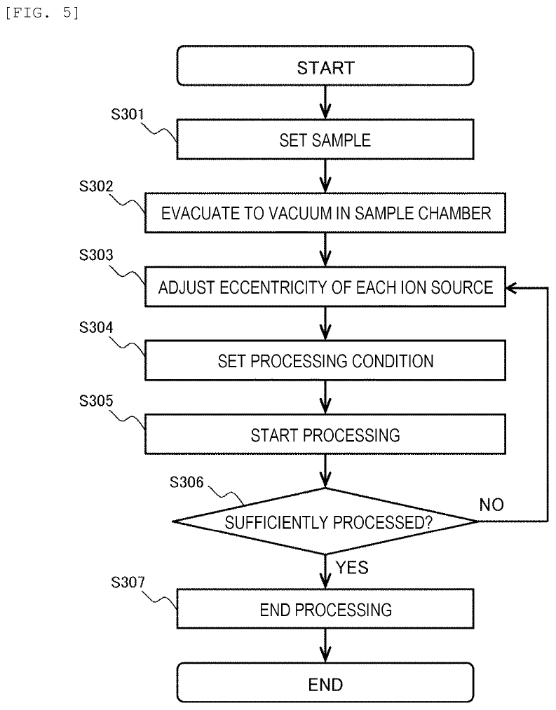

FIG. 5 is a flowchart showing a series of operations from sample setting to an end of the ion milling device 100. Details of each operation are as follows.

S301: The sample holder 105 where the sample 106 is set is mounted on the sample stage 104.

S302: The sample chamber 114 is evacuated to a high vacuum by the vacuum pump 115.

S303: The eccentricity dᵢ of each ion source relative to the sample rotation axis C is adjusted by the first ion source movable mechanism 102, the second ion source movable mechanism 108, and the third ion source movable mechanism 111, and the planar milling range is set. Specifically, when an ion beam diameter on the sample surface from the i-th ion source (i=1 to 3) is φᵢ, the eccentricity dᵢ is set to satisfy the desired planar milling range diameter R and satisfy (Equation 1) to (Equation 6) described above, and the i-th ion source is moved by the i-th ion source movable mechanism according to the eccentricity dᵢ.

S304: A processing condition is set for the first ion source 101, the second ion source 107, and the third ion source 110. The processing condition includes an ion beam diameter φ of an ion beam on the sample surface from each ion source, and since the ion beam diameter is determined by a profile of the ion beam emitted by the ion source, specifically, the ion beam diameter can be controlled by the acceleration voltage Va, the discharge voltage Vd, and the like.

An example of a method for measuring the ion beam diameter φ will be described. For example, in the case of the first ion source 101 in FIG. 1A, a conductive needle-like probe (for example, a carbon probe) having a minimized diameter is held such that a longitudinal direction is the Y-axis direction, and is moved in the X-axis direction on an XY plane including the tilt axis T. The ion beam diameter φ can be measured by plotting a relationship between a position of the probe in the X-axis direction and an ion beam current flowing through the probe. The ion beam diameter φ and/or an ion beam current amount measured according to the above-described measurement method while changing an irradiation condition of the ion beam to enable the ion source to set a condition under which the ion beam having the desired ion beam diameter φ can be emitted may be stored in the controller 118 in advance.

The processing condition includes an irradiation condition of the ion beam from each ion source, and the irradiation condition includes the discharge voltage Vd and the acceleration voltage Va applied from the high-voltage circuit and the gas flow rate controlled by the gas flow rate controller 207. As described above, when the relationship between the ion beam diameter φ and/or the ion beam current amount and the irradiation condition is registered in the controller 118, the irradiation condition such as the acceleration voltage Va and the discharge voltage Vd can be automatically determined based on the registered relationship according to the ion beam diameter φ and/or the ion beam current amount set in the controller 118, and the irradiation condition for the ion beam from each ion source can be set in the control unit 113.

S305: Sample processing is started.

S306: It is checked whether the processing is sufficiently performed. For example, when a processing time is set in the processing condition set in step S304, the processing time is followed. Here, an example will be described in which the determination is performed using the image sensor 116 that observes the processed shape from above. The determination is performed according to an image of the planar milling range about the sample rotation axis C captured by the image sensor 116. For example, when the sample 106 has a multilayer film structure in which different materials are stacked, a color of a layer exposed by planar milling differs depending on a material thereof. Therefore, it is determined whether a color of the image of the planar milling range about the sample rotation axis C captured by the image sensor 116 is the color of the layer to be exposed by the planar milling. When the processing is not sufficient, for example, when a part of the planar milling range is not the color of the layer to be exposed, the process returns to step S303, and the eccentricity of each ion source is adjusted such that an unexposed portion is preferentially processed. If the processing has sufficiently progressed, that is, when the entire planar milling range has the color of the layer to be exposed, the process proceeds to step S307 to end the processing. The determination may be performed visually, or the controller 118 may specify the planar milling range by image processing based on a sample image acquired by the image sensor 116 and determine a state of the exposed color, thereby automatically performing end determination and eccentricity adjustment.

### Second Embodiment

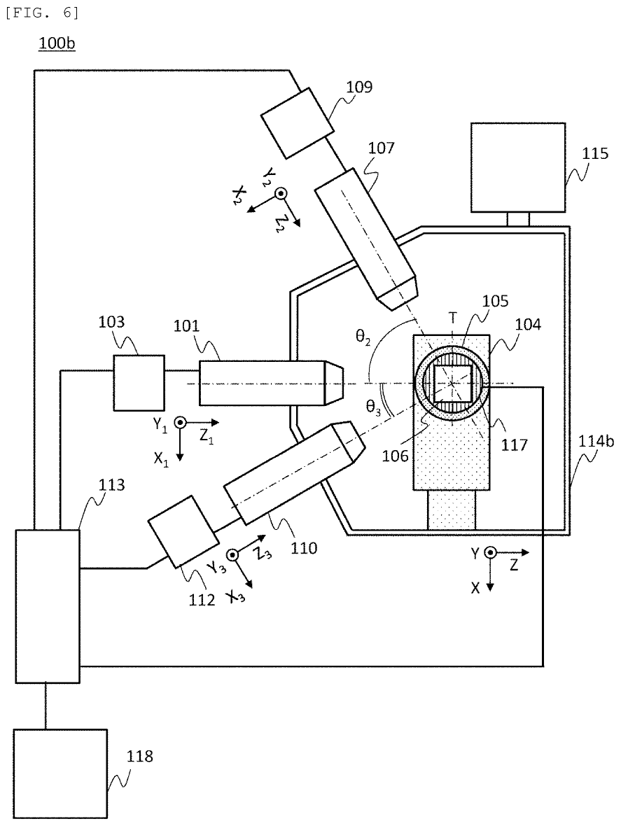

FIG. 6 is a schematic diagram of main parts of an ion milling device 100b in a second embodiment. For components shared with those in the first embodiment, the same reference signs are used. In the second embodiment, each ion source is attached to a sample chamber 114b without a movable mechanism, and a sample height adjustment mechanism 117 is provided on the sample holder 105. The sample height adjustment mechanism 117 is controlled by the control unit 113. The sample height adjustment mechanism 117 may be configured for manual control.

The three ion sources 101, 107, and 110 are attached such that the ion beam center axes thereof, that is, the Zᵢ-axes intersect at one point at the intersection of the surface of the sample 106 with the sample rotation axis C. At this time, the three ion sources are disposed such that the angle formed by the Z₁-axis and the Z₂-axis is θ₂ and the angle formed by the Z₁-axis and the Z₃-axis is θ₃.

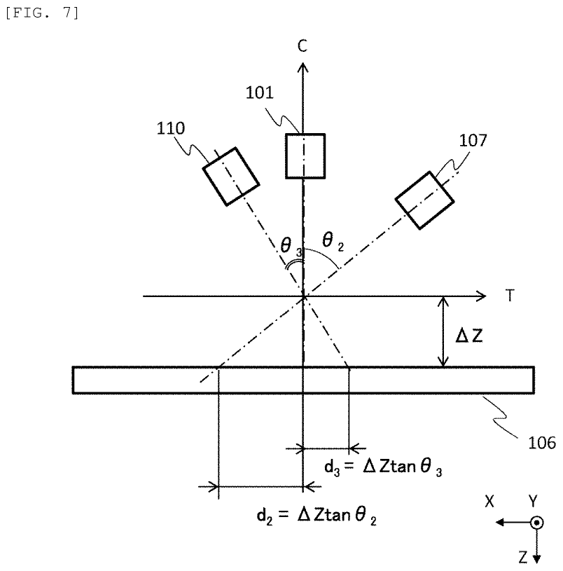

FIG. 7 is a schematic diagram showing a method for adjusting the eccentricity dᵢ of the ion source. Here, a state where the sample 106 is tilted about the tilt axis T such that the first ion source 101 and the sample 106 face each other is shown. Although ion beams emitted from the respective ion sources intersect at a certain point on the sample rotation axis C, by adjusting a sample height by the sample height adjustment mechanism 117, the sample surface deviates from the intersection of the ion beams and the same effect as when the ion sources are eccentrically offset can be obtained. As described above, since the angle formed by the Z₁-axis and the Z₂-axis is θ₂ and the angle formed by the Z₁-axis and the Z₃-axis is θ₃, eccentricities of the second ion source and the third ion source (distances between the sample rotation axis C and the ion beam center axes Z on the sample surface) have different values.

In FIG. 7, the ion sources are disposed on the same plane (XZ plane), and may alternatively not be disposed on the same plane. However, it is desirable that distances (W.D.) of the ion sources from an intersection of the ion beam center axes Z on the sample rotation axis C have the same value.

Assuming that the eccentricity of the second ion source is d₂ and the eccentricity of the third ion source is d₃ when the sample height is changed by AZ from the intersection of the ion beam center axes Z on the sample rotation axis C, d₂ and d₃ are given by the following (Equation 7) and (Equation 8).

$${d}_{2} = Δ Z tan {θ}_{2} \qquad ( Equation 7 )$$

$${d}_{3} = Δ Z tan {θ}_{3} \qquad ( Equation 8 )$$

The invention is not limited to the above embodiments, and includes various modifications. For example, the embodiment and the modification described above have been described in detail to facilitate understanding of the invention, and the invention is not necessarily limited to those including all the configurations described above. A part of a configuration of one embodiment or one modification can be replaced with a configuration of another embodiment or another modification, and a configuration of another embodiment or another modification can be added to a configuration of one embodiment or one modification. Another configuration may be added to a part of a configuration of each embodiment and each modification, or a part of a configuration of each embodiment and each modification may be deleted or replaced with another configuration.

For example, the number of ion sources is three in the above description, and may alternatively be two or four or more. An example has been described in which all the ion sources are on the same plane (XZ plane) in the initial state in the first embodiment and in the second embodiment, and there is no problem even when the ion sources are not on the same plane as long as the Zᵢ axes of the ion sources intersect at one point on the sample rotation axis C. Although the ion sources are fixed in the second embodiment, the ion sources may be provided via an angle tilting mechanism that can freely tilt at any angle while ensuring W.D. with respect to the sample. Accordingly, a degree of freedom in magnitude of the eccentricity for each ion source can be improved.

### REFERENCE SIGNS LIST

100, 100b: ion milling device
101: first ion source
102: first ion source movable mechanism
103: first high-voltage power supply
104: sample stage
105: sample holder
106: sample
107: second ion source
108: second ion source movable mechanism
109: second high-voltage power supply
110: third ion source
111: third ion source movable mechanism
112: third high-voltage power supply
113: control unit
114, 114b: sample chamber
115: vacuum pump
116: image sensor
117: sample height adjustment mechanism
118: controller
201: first cathode
202: second cathode
203: anode
204: permanent magnet
205: acceleration electrode
206: gas pipe
207: gas flow rate controller

1. An ion milling device comprising:
a sample chamber;
a sample stage which is disposed in the sample chamber and on which a sample holder with a sample set thereon is mounted;
a plurality of ion sources attached to the sample chamber via respective ion source movable mechanisms; and
a control unit, wherein
the sample stage is tiltable about a tilt axis and rotates the sample about a sample rotation axis orthogonal to the tilt axis,
the plurality of ion sources are adjusted by the respective ion source movable mechanisms to which the ion sources are attached such that eccentricities, each of which is a distance between an ion beam center axis and the sample rotation axis on a surface of the sample, are different from each other, and
the control unit performs milling by irradiating the sample, which is rotated about the sample rotation axis by the sample stage, with an unfocused ion beam from each of the plurality of ion sources.

2. The ion milling device according to claim 1, comprising:
a controller, wherein
a relationship between an ion beam diameter on the surface of the sample or an ion beam current amount of the ion beam emitted by the ion source and an irradiation condition of the ion beam from the ion source is registered in the controller, and
the controller determines the irradiation condition of the ion beam to be set in the control unit based on the relationship when the ion beam diameter on the surface of the sample or the ion beam current amount from each of the plurality of ion sources is set as a processing condition of the milling.

3. The ion milling device according to claim 2, wherein
the irradiation condition of the ion beam includes at least a discharge voltage and an acceleration voltage applied to the ion source.

4. The ion milling device according to claim 1, comprising:
a controller; and
an image sensor configured to capture an image of a processed surface formed on the surface of the sample by the milling, wherein
the controller determines progress of the milling based on the image of the processed surface captured by the image sensor.

5. The ion milling device according to claim 4, wherein
the controller adjusts the eccentricities of the plurality of ion sources when it is determined based on the image of the processed surface that the milling is insufficient.

6. The ion milling device according to claim 4, wherein
the controller determines the progress of the milling based on a color of the image of the processed surface.

7. An ion milling device comprising:
a sample chamber;
a sample stage which is disposed in the sample chamber and on which a sample holder with a sample set thereon via a sample height adjustment mechanism is mounted;
a plurality of ion sources attached to the sample chamber; and
a control unit, wherein
the sample stage is tiltable about a tilt axis and rotates the sample about a sample rotation axis orthogonal to the tilt axis,
the plurality of ion sources are disposed such that ion beam center axes thereof intersect at one point on the sample rotation axis, and
the control unit performs milling by irradiating the sample, which is rotated about the sample rotation axis by the sample stage, with an unfocused ion beam from each of the plurality of ion sources in a state where a surface of the sample is adjusted to a height different from the one point by the sample height adjustment mechanism.

8. The ion milling device according to claim 7, wherein
the plurality of ion sources include first to third ion sources,
the first ion source is interposed between the second ion source and the third ion source, and
an angle formed by an ion beam center axis of the first ion source and an ion beam center axis of the second ion source is different from an angle formed by the ion beam center axis of the first ion source and an ion beam center axis of the third ion source.

9. A processing method for milling a sample using an ion milling device, wherein
the ion milling device includes a sample chamber, a sample stage which is disposed in the sample chamber and on which a sample holder with a sample set thereon is mounted, a plurality of ion sources attached to the sample chamber, and a control unit,
the sample stage is tiltable about a tilt axis and rotates the sample about a sample rotation axis orthogonal to the tilt axis,
the plurality of ion sources are adjusted such that eccentricities, each of which is a distance between an ion beam center axis and the sample rotation axis on a surface of the sample, are different from each other, and
the control unit performs milling by irradiating the sample, which is rotated about the sample rotation axis by the sample stage, with an unfocused ion beam from each of the plurality of ion sources.

10. The processing method according to claim 9, wherein
the ion milling device includes a controller,
a relationship between an ion beam diameter on the surface of the sample or an ion beam current amount of the ion beam emitted by the ion source and an irradiation condition of the ion beam from the ion source is registered in the controller, and
the controller determines the irradiation condition of the ion beam to be set in the control unit based on the relationship when the ion beam diameter on the surface of the sample or the ion beam current amount from each of the plurality of ion sources is set as a processing condition of the milling.

11. The processing method according to claim 10, wherein
the irradiation condition of the ion beam includes at least a discharge voltage and an acceleration voltage applied to the ion source.

12. The processing method according to claim 9, wherein
the ion milling device includes a controller and an image sensor that captures an image of a processed surface formed on the surface of the sample by the milling, and
the controller determines progress of the milling based on the image of the processed surface captured by the image sensor.

13. The processing method according to claim 12, wherein
the controller adjusts the eccentricities of the plurality of ion sources when it is determined based on the image of the processed surface that the milling is insufficient.

14. The processing method according to claim 12, wherein
the controller determines the progress of the milling based on a color of the image of the processed surface.
